(19) United States
(12) Patent Application Publication
(10) Pub. No.: US 2026/0372073 A1
(43) Pub. Date: Nov. 19, 2026

(54) ELECTRONIC DEVICES AND METHODS OF MANUFACTURING ELECTRONIC DEVICES

(71) Applicant: Amkor Technology Singapore Holding Pte. Ltd.

(72) Inventors: Hee Jun Jang, Chungcheonbuk-do (KR); Soo Hyun Kim, Incheon (KR); Seok Woo Yun, Incheon (KR); Tae Kyeong Hwang, Incheon (KR); Won Chul Do, Seoul (KR)

(73) Assignee: Amkor Technology Singapore Holding Pte. Ltd., (omitted)

(21) Appl. No.: 19/206,877

(22) Filed: May 13, 2025

(51) Int. Cl. H10W 40/22; H10W 40/25; H10W 70/00; H10W 70/02; H10W 70/05; H10W 70/685; H10W 72/00; H10W 74/01; H10W 74/10; H10W 74/15; H10W 90/00

(52) U.S. Cl. CPC H10W 40/22; H10W 40/257; H10W 70/02; H10W 70/05; H10W 70/099; H10W 70/685; H10W 74/012; H10W 74/016; H10W 74/117; H10W 74/121; H10W 74/15; H10W 90/401; H10W 90/701; H10W 72/072; H10W 72/073; H10W 74/142; H10W 90/725; H10W 90/734

(57) ABSTRACT

In one example, an electronic device can comprise a base substrate. The base substrate can comprise a conductive structure and a dielectric structure interleaved with the conductive structure. An electronic module is coupled to the base substrate and can comprise a module substrate, an electronic component coupled to the module substrate, and a first encapsulant. A metal layer can be disposed over the upper side of the first encapsulant and of the electronic components. A second encapsulant can be disposed around the electronic module and can define at least a portion of a TIM retention region. A thermal interface material (TIM) is disposed over the second encapsulant, over the metal layer, and in the TIM retention region. A lid can be disposed over the second encapsulant and the metal layer, and the lid can be coupled to the TIM. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2M show cross-sectional views of an example method for manufacturing an example electronic device.

FIG. 2J1 and 2J2 show a cross-sectional views of example channels in greater detail.

FIG. 3 shows a cross-sectional view of an example electronic device.

FIG. 4 shows a cross-sectional view of an example electronic device.

FIG. 5 shows a cross-sectional view of an example electronic device.

FIG. 6 shows a cross-sectional view of an example electronic device.

FIG. 7 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used to describe various elements, and these elements should not be limited by these terms. These terms are only used to distinguish one element from another. Thus, for example, a first element discussed in the present disclosure could be termed a second element without departing from the teachings of the present disclosure.

Unless specified otherwise, the term “coupled” can be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” can be used to describe two elements directly contacting each other or describe two elements indirectly coupled by one or more other elements. Unless specified otherwise, the term “coupled” can refer to a mechanical or electrical coupling.

### DESCRIPTION

An example electronic device can comprise a base substrate. The base substrate can comprise a conductive structure and a dielectric structure interleaved with the conductive structure. An electronic module is coupled to the base substrate and can comprise a module substrate, an electronic component coupled to the module substrate, and a first encapsulant disposed around lateral sides of the electronic components. An upper side of the first encapsulant can be substantially coplanar with an upper side of the electronic components. A metal layer can be disposed over the upper side of the first encapsulant and the upper side of the electronic components. A second encapsulant can be disposed around the electronic module, and the second encapsulant can define at least a portion of a TIM retention region. A thermal interface material (TIM) is disposed over the second encapsulant, over the metal layer, and in the TIM retention region. A lid can be disposed over the second encapsulant and the metal layer, and the lid can be coupled to the TIM.

In various examples, the second encapsulant comprises a channel formed in a first side of the second encapsulant and at least partially defining the TIM retention region. A first height of a floor of the channel above the base substrate can be less than a second height of the first side of the second encapsulant above the base substrate. The second encapsulant can include a step portion at least partially defining the TIM retention region. An adhesive can be coupled to a perimeter of the base substrate and to a perimeter of the lid, and a gap can be defined between an inner sidewall of the lid and an outer sidewall of the second encapsulant. An adhesive can be coupled to the lid and the second encapsulant. An inner sidewall of the adhesive at least partially defines the TIM retention region. The second encapsulant can include a serrated side at least partially defining the TIM retention region. In some examples, a trench at least partially defines the TIM retention region, and a sidewall of the trench comprises an inner wall of the second encapsulant. The inner wall of the second encapsulant can connect a first side of the second encapsulant and a second side of the second encapsulant, and a floor of the trench can include a portion of the first side of the second encapsulant and an upper side of the metal layer. The second encapsulant can include a channel including an inner sidewall and an outer sidewall, and the inner sidewall can be closer to the electronic module than the outer sidewall. A first height of the inner sidewall can be less than a second height of the outer sidewall.

Another example electronic device can include a base substrate and an electronic module coupled to the base substrate. The electronic module can include electronic components, a first encapsulant disposed around lateral sides of the electronic components, and a metal layer disposed over the first encapsulant and the electronic components. A second encapsulant can be disposed around the electronic module and the metal layer. The second encapsulant and the metal layer can at least partially define a TIM retention region. A TIM can be disposed over the second encapsulant and over the metal layer, and the TIM is retained within a footprint of the base substrate. A lid can be disposed over the second encapsulant and the metal layer with the lid coupled to the TIM.

An example method of manufacturing an electronic device can include the step of providing a base substrate comprising a conductive structure and a dielectric structure interleaved with the conductive structure. An electronic module can be provided over the base substrate and can include an electronic component and a first encapsulant around lateral sides of the electronic component. The method can include the steps of providing a metal layer over the first encapsulant and the electronic component, providing a second encapsulant over the base substrate and around lateral sides of the electronic module, and providing an adhesive over the second encapsulant. The adhesive can define a lateral boundary of a TIM retention region over the second encapsulant. A TIM can be provided over the second encapsulant and the metal layer. A lid can be provided over the TIM with the lid coupled to the second encapsulant by the adhesive.

Other examples are included in the present disclosure. Such examples may be found in the figures, in the claims, or in the description of the present disclosure.

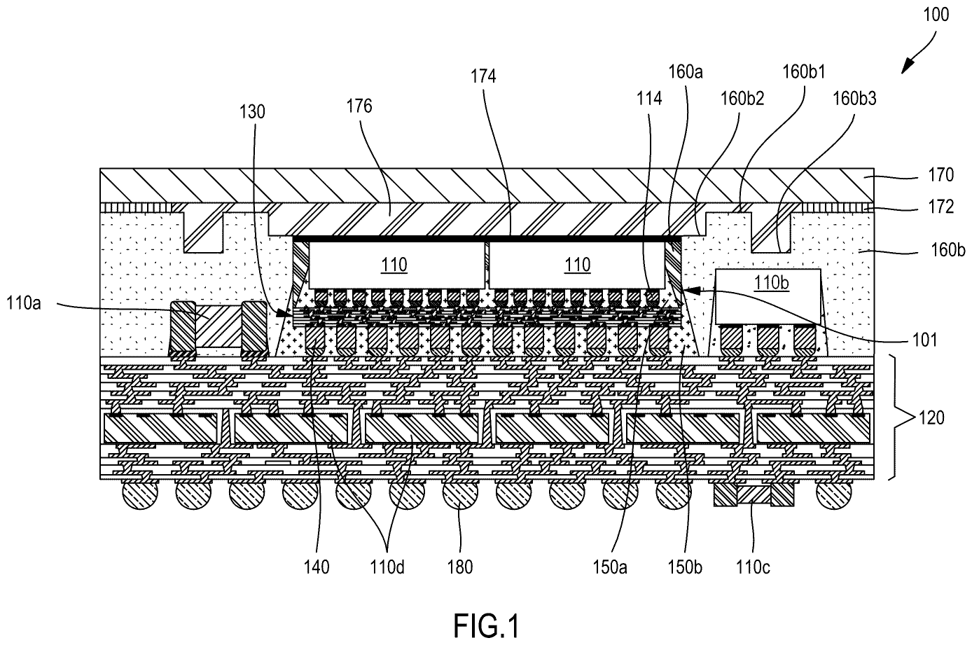

FIG. 1 shows a cross-sectional view of example electronic device 100. In the example shown in FIG. 1, electronic device 100 can comprise electronic module 101, electronic component(s) 110a, electronic component(s) 110b, electronic component(s) 110c, base substrate 120, underfill 150b, encapsulant 160b, lid 170, and external interconnects 180. Electronic module 101 can comprise electronic component(s) 110, module substrate 130, interconnects 140, underfill 150a, and encapsulant 160a.

Electronic components 110 can coupled to module substrate 130 via connectors 114. Electronic module 101 can be coupled to base substrate 120 via interconnects 140. In some examples, module 101 can include a metallization layer 174 over electronic components 110 and encapsulant 160a. In some examples, base substrate 120 can include electronic components 110d embedded therein.

Encapsulant 160b can be disposed around electronic module 101, electronic component(s) 110a, and electronic component(s) 110b. An upper side 160b1 of encapsulant 160b can include step portion 160b2 and channel 160b3. A thermal interface material (TIM) 176 can be disposed between lid 170 and electronic module 101. In some examples, a lid adhesive 172 can be located between lid 170 and upper side 160b1 of encapsulant 160b. Step portion 160b2 and channel 160b3 can control or limit the flow of TIM 176.

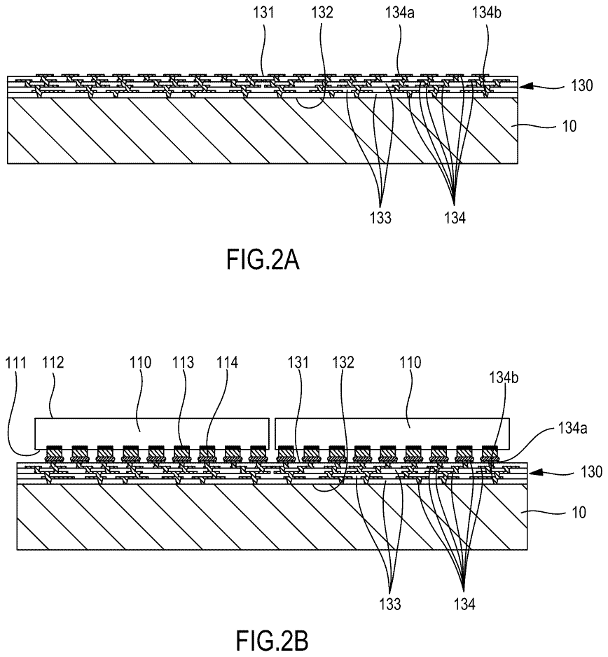

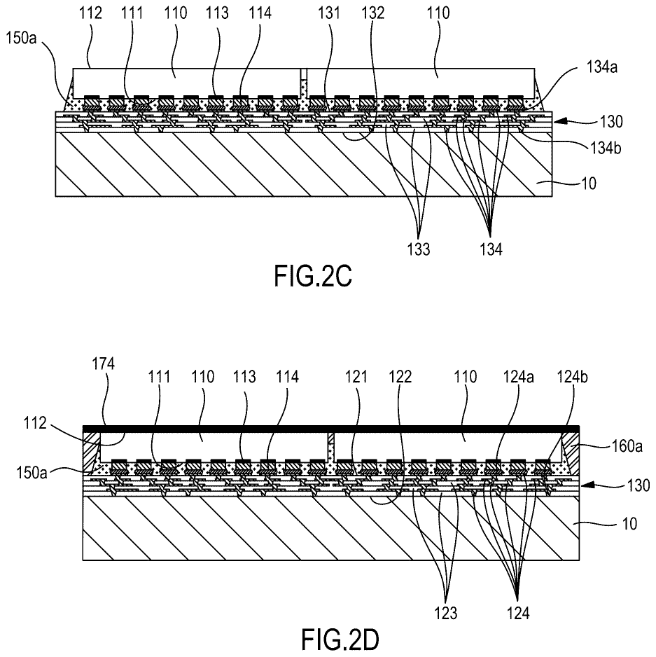

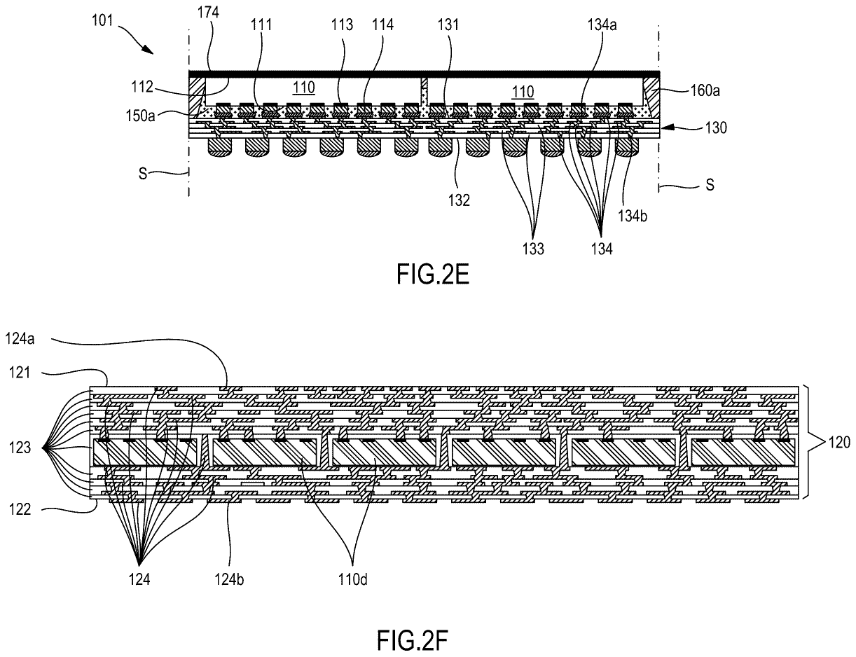

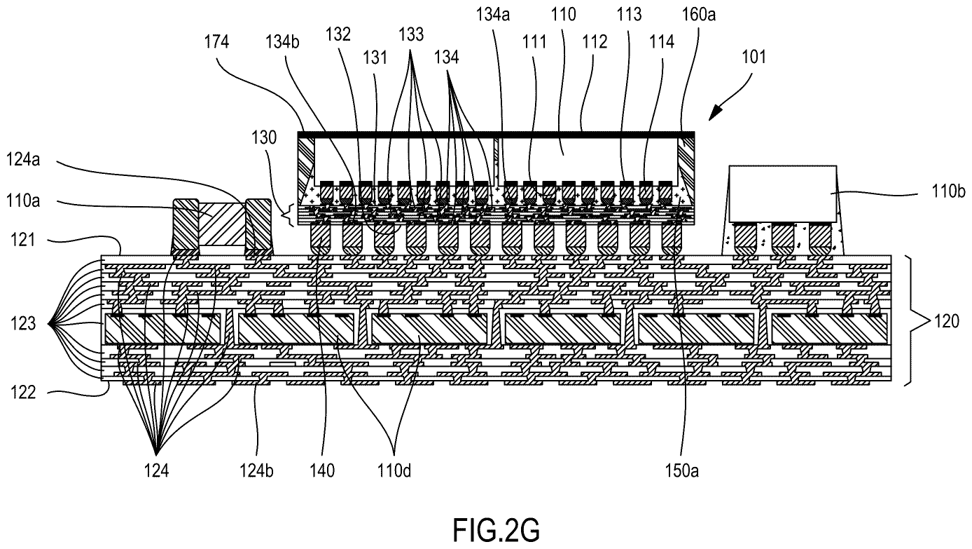

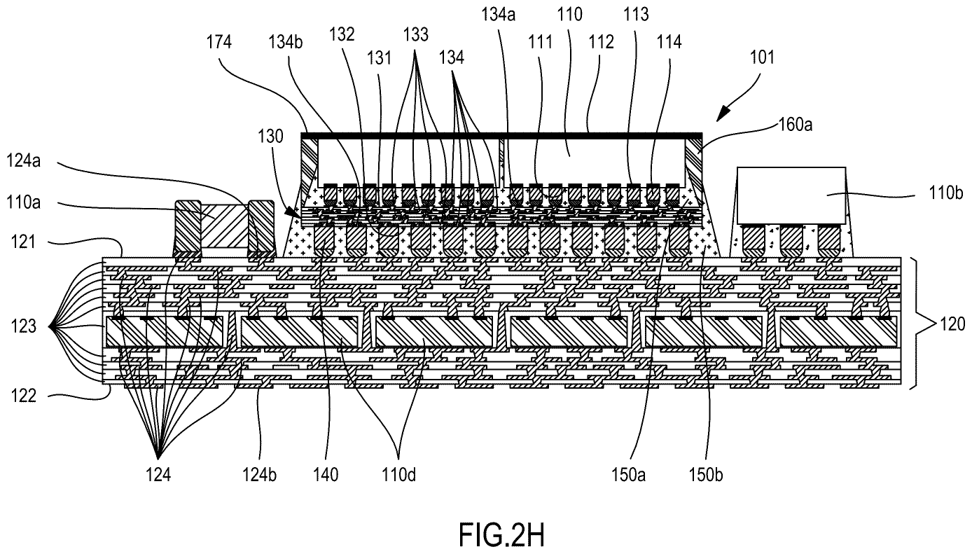

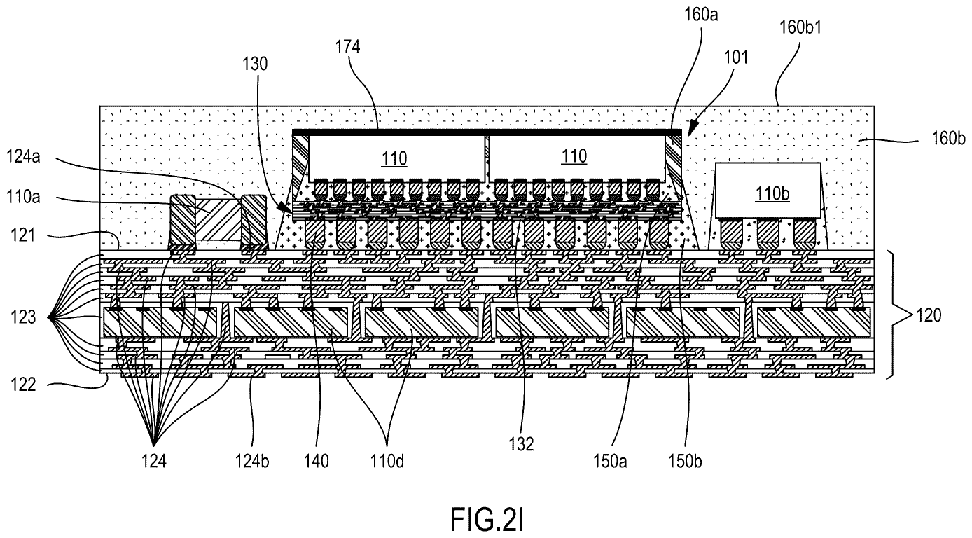

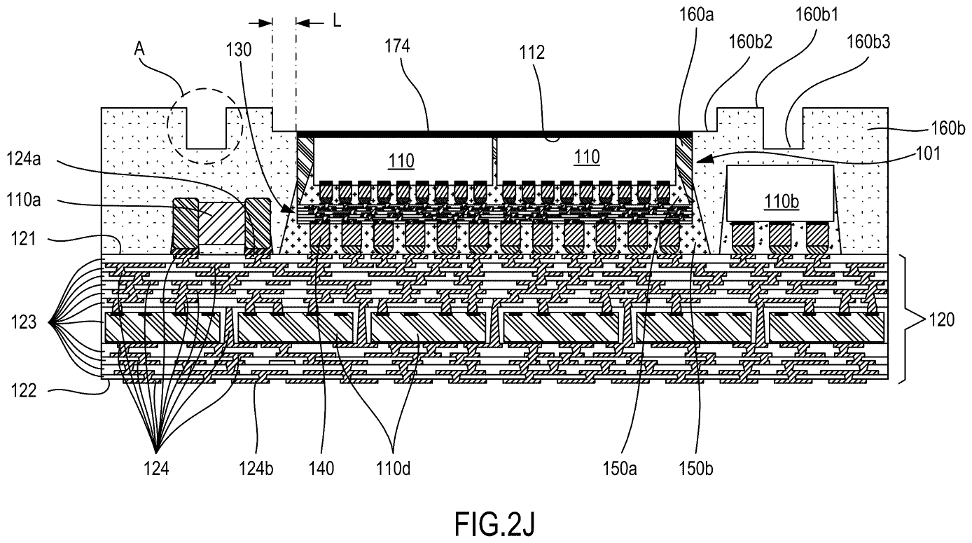

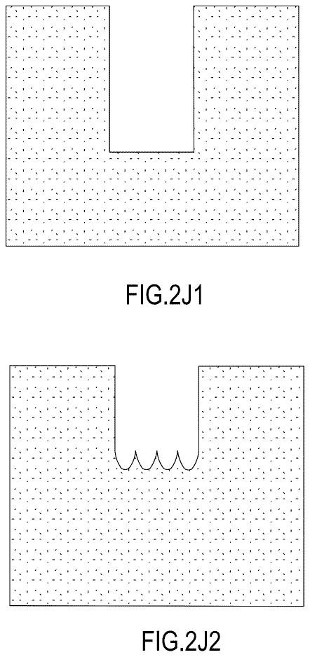

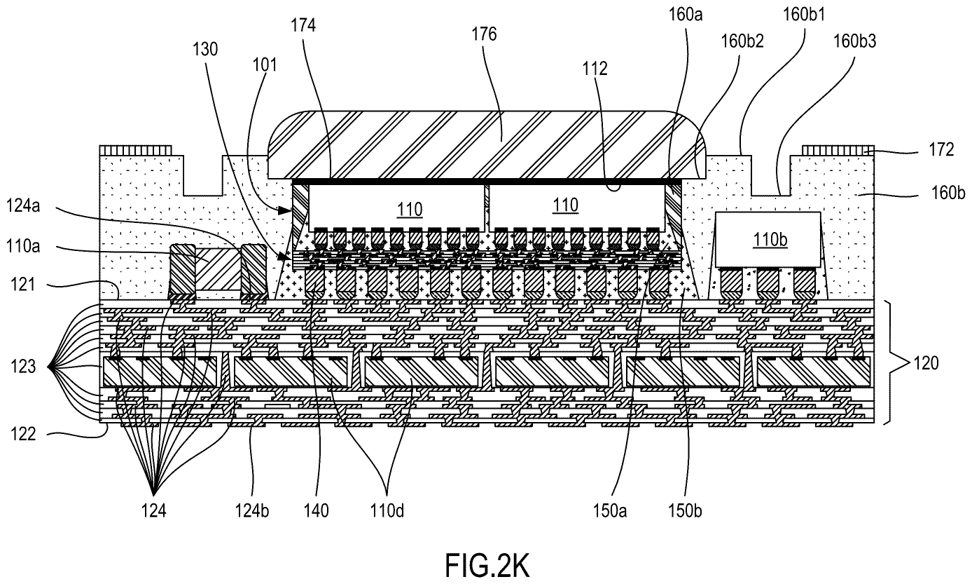

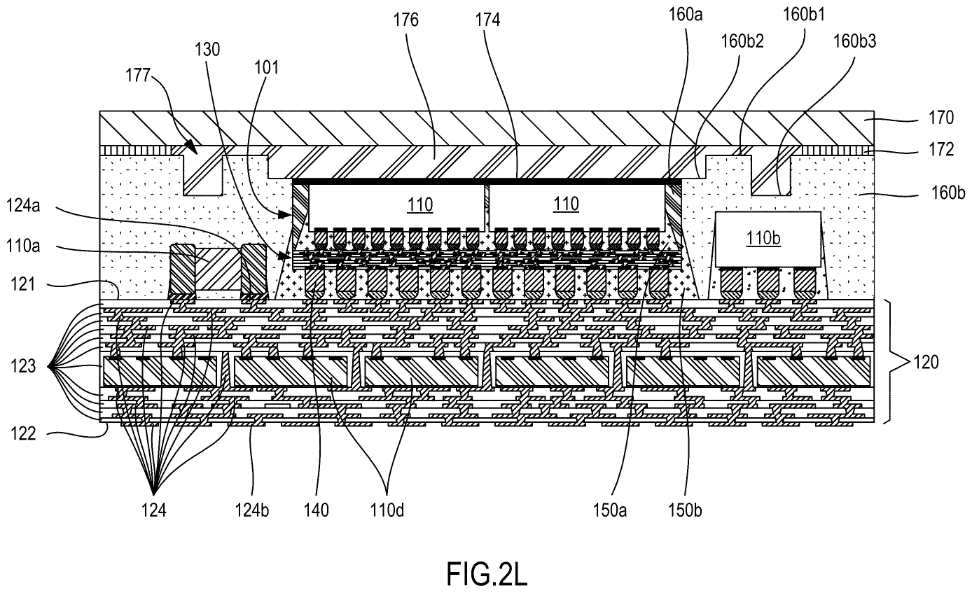

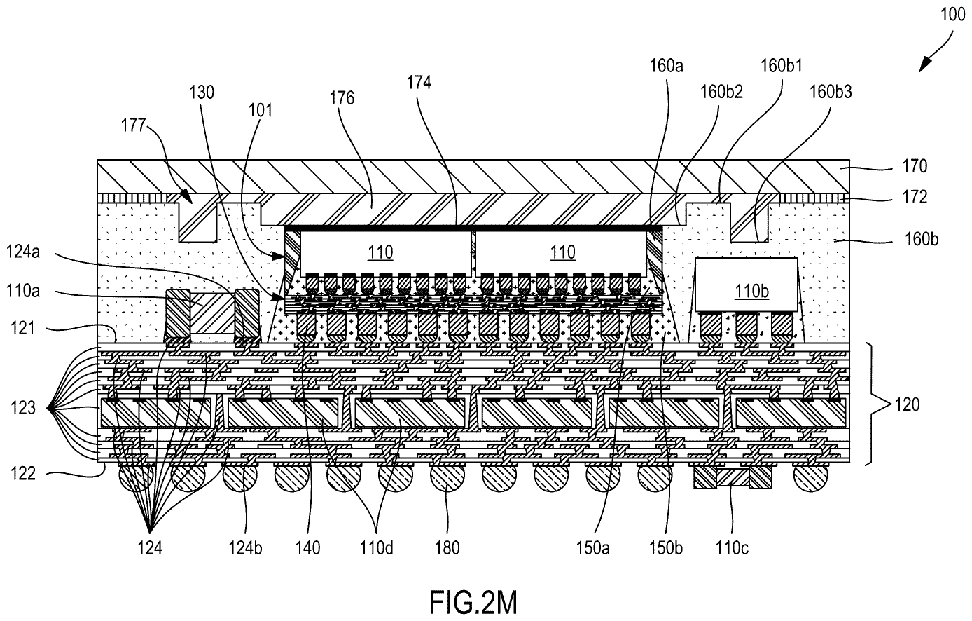

FIGS. 2A to 2M show cross-sectional views of an example method for manufacturing an example electronic device, such as electronic device 100 in FIG. 1.

FIG. 2A shows a cross-sectional view of electronic module 101 of electronic device 100 at an early stage of manufacture. In the example shown in FIG. 2A, module substrate 130 can be provided on carrier 10. Module substrate 130 can comprise dielectric structure 133 and conductive structure 134. Layers or elements of dielectric structure 133 and conductive structure 134 can be sequentially provided over carrier 10.

Carrier 10 can be a planar support structure having a rectangular, square, or circular shape, when viewed from above. In some examples, carrier 10 can comprise or be referred to as a plate, a board, a wafer, a panel, or a strip. Carrier 10 can be made of, for example, metal, ceramic, glass, or semiconductor or wafer material. In some examples, the thickness of carrier 10 can range from approximately 300 μm to approximately 2000 μm, and the width of carrier 10 can range from approximately 100 millimeters (mm) to approximately 300 mm. In some examples, the width of carrier 10 can range from approximately 300 mm to approximately 650 mm. As used herein to describe numerical values, the term approximately can mean +/−5%, +/−10%, +/−15%, +/−20%, or +/−25%. In some examples, carrier 10 can have a width of up to 700 mm. Carrier 10 can support the simultaneous (or nearly simultaneous) manufacture of multiple electronic modules 101.

In some examples, carrier 10 can comprise a temporary bond layer provided between the upper side of carrier 10 and an outer side 132 of module substrate 130. The temporary bond layer can be referred to as a temporary bonding film, a temporary bonding tape, or a temporary bonding coating. In some examples, the temporary bond layer can be a heat-release tape (or film) or a light-release tape (or film). The temporary bond layer can have its adhesive strength weakened or removed by heat, light, physical force, or chemical force. The temporary bond layer can enable easy separation of module substrate 130 from carrier 10.

Dielectric structure 133 can be provided over carrier 10 using physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), spin coating, spray coating, dip coating, rod coating, or any other suitable deposition process. Dielectric structure 133 can comprise one or more layers of organic dielectric material (e.g., polyimide (PI), benzocyclobutene (BCB), polybenzoxazole (PBO), phenolic resin, or Ajinomoto Buildup Film (ABF)), inorganic dielectric material (e.g., silicon oxide (SiO2), silicon nitride (Si3N4), silicon oxynitride (SiON), tantalum pentoxide (Ta2O5), or aluminum oxide (Al2O3)), or other dielectric material having similar insulating and structural properties. The thickness of individual layers of dielectric structure 123 can range from approximately 2 micrometer (μm) to approximately 30 μm, approximately 2 μm to approximately 15 μm, or approximately 2 μm to approximately 10 μm. The combined thickness of the layers of dielectric structure 133 can be substantially equal to or can define the thickness of module substrate 130. Dielectric structure 133 can maintain the shape of module substrate 130 and can also structurally support conductive structure 134. In some examples, the thickness of module substrate 130 can range from approximately 10 μm to approximately 80 μm.

Conductive structure 134 can be interleaved with layers or elements of dielectric structure 133. Conductive structure 134 can comprise or be referred to as one or more conductive layers defining signal distribution elements, traces, vias, pads, conductive patterns, conductive paths, wiring patterns, circuit patterns, or under bump metallization (UBM). Conductive structure 134 can be formed using PVD, CVD, electrolytic plating, electroless plating process, or other suitable metal deposition process. Conductive structure 124 can comprise one or more layers of aluminum (Al), titanium (Ti), titanium tungsten (TiW), copper (Cu), tin (Sn), nickel (Ni), gold (Au), silver (Ag), palladium (Pd), or other suitable electrically conductive material.

Conductive structure 134 can comprise inward terminals 134a on an inner side 131 of module substrate 130 and outward terminals 134b on an outer side 122 of module substrate 130. Outer side 132 of module substrate 130 is opposite (e.g., oriented away from) inner side 131 of module substrate 130. In some examples, inward terminals 134a and/or outward terminals 134b can comprise or be referred to as pads, lands, studs, or UBM.

In some examples, module substrate 130 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and can interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), and/or SiON. The inorganic dielectric layer(s) can be formed by growing the inorganic dielectric layers using an oxidation or nitridization process instead of using photo-defined organic dielectric materials. Such inorganic dielectric layers can be filler-fee, without strands, weaves, or other dissimilar inorganic particles. In some examples, the RDL substrates can omit the permanent core structure associated with preformed laminate substrates, as described below. Any of the substrates of the present disclosure can comprise an RDL substrates.

In some examples, module substrate 130 can be a pre-formed (or laminate) substrate. The pre-formed/laminate substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers, can be attached as a pre-formed film rather than as a liquid, and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising BT or FR4, and dielectric and conductive layers can be formed on the permanent core structure. In other examples, the pre-formed substrate can be a coreless substrate omitting the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Unless specified otherwise, any of the substrates in this disclosure can comprise a pre-formed substrate.

FIG. 2B shows a cross-sectional view of electronic module 101 at a later stage of manufacture. In the example shown in FIG. 2B, one or more electronic component(s) 110 can be provided on inner side 131 of module substrate 130. Electronic components 110 can be coupled to inward terminals 134a of conductive structure 134.

Electronic components 110 can comprise inner side 111 and outer side 112. Outer side 112 of electronic component 110 is opposite inner side 111. In some examples, inner side 111 of electronic component 110 can comprise or be referred to as an active side, and outer side 112 can comprise or be referred to as an inactive side or back side.

Electronic components 110 can comprise contact pads 113 on inner side 111. Contact pads 113 can be provided in rows and columns along inner side 111. In some examples, contact pads 113 can comprise or be referred to as bond pads, contact pads, pads, studs, or pillars. In some examples, contact pads 113 can be exposed through a SiO2 film or SiN film located over inner side 111. In some examples, redistribution layers (e.g., comprising organic dielectric layers) can be between contact pads 113 and the active circuity (e.g., the transistor and back-end-of-line (BEOL) regions) of electronic component 110.

Connectors 114 can couple contact pads 113 of electronic component 110 to inward terminals 124a of module substrate 130. In some examples, connectors 114 can comprise or be referred to as bumps, SnPb bumps, leadfree bumps, CuP, stud bumps, pillars, posts, or solder-capped posts. Connectors 114 can be provided on contact pads 113 by, for example, plating, ball-drop, solder reflow, or any other suitable deposition process.

In some examples, pick-and-place equipment can pick up electronic components 110 and place them on inner side 131 of module substrate 130. Connectors 114 of electronic component 110 can be positioned on inward terminals 124a of conductive structure 134. Contact pads 113 of electronic component 110 can be electrically coupled to inward terminals 124a through connectors 114 through, for example, a reflow, thermal compression, or laser assisted bonding process of connectors 114 to inward terminals 134a. In some examples, electronic components 110 can comprise or be referred to as a die, a chip, or a passive component. In some examples, one or more of electronic components 110 of module 101 can comprise a package. For example, a first electronic components 110 can comprise memory die or packages and a second electronic component 110 can comprise a logic die (e.g., a central processing unit (CPU), graphics processing unit (GPU), or application specific integrated circuit (ASIC)). In some examples, the memory die or package can comprise a high bandwidth memory (HBM) device. In some examples, the HBM device can include a controller die having a stack of memory die located thereon. The controller die and memory stack can be encapsulated. In some examples, the overall thickness of electronic components 110 can range from approximately 50 μm to approximately 780 μm.

FIG. 2C shows a cross-sectional view of electronic module 101 at a later stage of manufacture. In the example shown in FIG. 2C, underfill 150a can be provided between electronic components 110 and module substrate 130. Underfill 150a can be positioned between inner side 111 of electronic component 110 and inner side 131 of module substrate 130. Underfill 150a can contact inner side 111 of electronic component 110 and inner side 131 of module substrate 130. In some examples, underfill 150a can surround and contact connectors 114.

Underfill 150a can comprise or be referred to as an electrically insulating material and can be free of inorganic fillers. In some examples, underfill 150a can comprise or be referred to as a capillary underfill (CUF), a nonconductive paste (NCP), a nonconductive film (NCF), an anisotropic conductive film (ACF), or an anisotropic conductive paste (ACP). In some examples, underfill 150a can be cured after being provided between electronic components 110 and module substrate 130. Underfill 150a can help reduce occurrences of electronic components 110 being separated from module substrate 130.

FIG. 2D shows a cross-section of electronic module 101 at a later stage of manufacture. In the example shown in FIG. 2D, encapsulant 160a can be provided over module substrate 130 and electronic components 110. In some examples, encapsulant 160a can contact underfill 150a, inner side 131 of module substrate 130, and the lateral sides of electronic components 110. In some examples, encapsulant 160a can be between inner side 131 of module substrate 130 and inner side 111 of electronic components 110. For example, encapsulant 160a can be a molded underfill (MUF) and can replace underfill 150a.

In some examples, encapsulant 160a can comprise or be referred to as a body or mold. Encapsulant 160a can comprise an epoxy mold compound, a resin, an organic polymer with an inorganic filler, a curing agent, a catalyst, a coupling agent, a colorant, or a flame retardant. Encapsulant 160a can be formed by compression molding, transfer molding, liquid body molding, vacuum lamination, paste printing, film-assisted molding, or any other suitable process. In some examples, encapsulant 160a can initially be provided over outer side 112 of electronic components 110, and an upper portion of encapsulant 160a can be removed to expose outer side 112 of electronic components 110. The upper side of encapsulant 160a and outer side 112 of electronic component 110 can be coplanar. Encapsulant 160a can protect electronic components 110 from external factors.

In some examples a back-side metallization (BSM) or metal layer 174 can be provided over electronic components 110, and over encapsulant 160a. Although BSM 174 is depicted as added before singulation in the example of FIG. 2D, BSM 174 can be provided at a later stage. In some examples BSM 174 can be provided after encapsulant 160b (of FIG. 2J) is provided. A trench or opening can be formed over exposed electronic components 110, in such examples, to receive the BSM 174.

Metal layer 174 can be provided to cover outer side 112 of electronic components 110 and the upper side of encapsulant 160a. Metal layer 174 can be in contact with outer side 112 of electronic component 110 and the upper side of encapsulant 160a. In some examples, metal layer 174 can comprise or be referred to as a BSM plating layer, a conductive layer, or a conductive film. For example, metal layer 174 can be provided by electrolytic plating, electroless plating, sputtering, or physical vapor deposition (PVD). In some examples, metal layer 174 can be made of gold (Au) or silver (Ag). In some examples, metal layer 174 can comprise a multi-layer metal stack. For example, metal layer can comprise an adhesion layer (e.g., Ti or TiW) applied on outer side 112 encapsulant 160a, a barrier layer (e.g., Ni or NiV) applied on the adhesion layer, and a wetting layer (e.g., Au or Ag) applied on barrier layer. In some examples, the thickness of metal layer 174 can range from approximately 0.3 μm to approximately 10 μm.

FIG. 2E shows a cross-sectional view of electronic module 101 at a later stage of manufacture. In the example shown in FIG. 2E, carrier 10 is removed, individual electronic modules 101 are singulated from one another, and interconnects 140 are provided on outer side 132 of module substrate 130.

In accordance with various examples, carrier 10 can be removed from module substrate 130. For example, heat, light, a chemical solution, or physical force can be applied to separate carrier 10 from outer side 132 of module substrate 130. Removal of carrier 10 exposes outer side 122 of module substrate 130.

Interconnects 140 can be coupled to outward terminals 134b located on outer side 132 of module substrate 130. Interconnects 140 can be electrically coupled to electronic components 110 through conductive structure 134 of module substrate 130. In some examples, interconnects 140 can comprise Sn, Ag, lead (Pb), Cu, Sn—Pb, Sn37-Pb, Sn95—Pb, Sn—Pb—Ag, Sn—Cu, Sn—Ag, Sn—Au, Sn—Bi, or Sn—Ag—Cu. For example, interconnects 140 can be formed by forming a conductive material including solder on an outward terminals 134b of module substrate 130 through a ball drop process, and then through a reflow process. Interconnects 140 can comprise or be referred to as conductive balls, such as solder balls, conductive pillars, such as copper pillars, or conductive posts having solder caps formed on copper pillars.

After providing interconnects 140, a singulation process can be performed to provide individual electronic modules 101. Singulation can comprise sawing along singulation lines S. For example, electronic modules 101 can be singulated by cutting through encapsulant 160a and module substrate 130. After singulation, the lateral sides of encapsulant 160a can be coplanar with the lateral sides of module substrate 130. Electronic module 101 can comprise electronic components 110, module substrate 130, interconnects 140, and encapsulant 160a. In some examples, electronic module 101 can comprise underfill 150a.

FIG. 2F shows a cross-sectional view of electronic device 100 at a later stage of manufacture. In the example shown in FIG. 2F, base substrate 120 can be provided.

In accordance with various examples, base substrate 120 can comprise inner side 121 and outer side 122 opposite to inner side 121. Electronic module 101 and electronic components 110a can be provided over and coupled to inner side 121 of base substrate 120. Outer side 122 of base substrate 120 can be configured for mounting electronic device 100 to external components or boards. For example, as described with reference to FIG. 2M, external interconnects 180 can located on and coupled to outer side 122 of base substrate 120.

Base substrate 120 can comprise dielectric structure 123 and conductive structure 124. In some examples, dielectric structure 123 can comprise or be referred to as one or more stacked dielectric layers. For instance, the one or more dielectric layers can comprise, one or more core layers, polymer layers, pre-preg layers, or solder mask layers stacked on each other. One or more layers or elements of conductive structure 124 can be interleaved with elements or layers of dielectric structure 123. In some examples, dielectric structure 123 can comprise a copper clad laminate, flame retardant material (e.g., FR4 comprising laminated layers of copper foil and glass fiber fabric), BT, PI, BCB, PBO, ABF, resin, mold compound, ceramic, glass, or silicon. Dielectric structure 123 can maintain the shape of base substrate 120 and can structurally support conductive structure 124.

Conductive structure 124 can comprise or be referred to as one or more conductive layers defining signal distribution elements, traces, vias, pads, conductive patterns, conductive paths, wiring patterns, circuit patterns, or UBM. In some examples, conductive structure 124 can comprise one or more layers of Cu, Al, Sn, Ti, TiW, Au, Ag, Ni, Pd, or combinations or alloys thereof. The thickness of conductive structure 124 can range from approximately 1 μm to approximately 50 μm. The thickness of conductive structure 124 can refer to individual layers of conductive structure 124. Conductive structure 124 can provide electrical signal paths (e.g., vertical paths and horizontal paths) through dielectric structure 123.

Conductive structure 124 can comprise substrate inward terminals 124a provided along inner side 121 of base substrate 120, and substrate outward terminals 124b provided along outer side 122 of base substrate 120. In some examples, substrate inward terminals 124a and substrate outward terminals 124b can comprise or be referred to as pads, lands, or UBM. Layers and elements of conductive structure 124 can electrically couple substrate inward terminals 124a with substrate outward terminals 124b.

Base substrate 120 can comprise a core or be coreless. In some examples, base substrate 120 can comprise or be referred to as pre-formed or laminate substrate, as previously described. In some examples, base substrate 120 can comprise or be referred to as a build-up or RDL substate, as previously described. In some examples, an area of base substrate 120 can be adjusted or selected according to the area or number of electronic modules 101 and electronic components 110a and 110b coupled thereto. In some examples, base substate 120 can have an area of approximately 1 mm by 1 mm to approximately 150 mm by 150 mm. Base substrate 120 can have a thickness of approximately 0.2 mm to approximately 4 mm.

Electronic components 110d can be embedded in base substrate 120. Electronic component 110d can include an upper side, a lower side, and a side wall being in contact with dielectric structure 123 of base substrate 120. Electronic component 110d can comprise a contact pad, and the contact pad can be electrically connected to conductive structure 124 of base substrate 120. Electronic component 110d can be electrically connected to electronic components 110, 110a, and 110b coupled to inner side 121 of base substrate 120 through conductive structure 124 of base substrate 120. In some examples such as the example depicted later in FIG. 2M, electronic components 110d can be electrically connected to external interconnects 180 and electronic component 110c coupled to outer side 122 of base substrate 120. Electronic component 110d can comprise or be referred to as a die, a chip, a package, or a passive component. For example, electronic component 110d can include an active die, an integrated passive device, a power device, a capacitor, a land-side capacitor (LSC), or other embedded component. In some examples, the overall thickness of electronic component 110d can range from approximately 50 μm to approximately 1500 μm.

FIG. 2G shows a cross section of example electronic device 100 at a later stage of manufacture. In the example shown in FIG. 2G, electronic module 101 and electronic components 110a and 110b can be provided on base substrate 120. Electronic module 101 can comprise electronic components 110, module substrate 130, interconnects 140, and encapsulant 160a. In some examples, electronic module 101 can comprise underfill 150a. Electronic module 101 can be provided on inner side 121 of base substrate 120.

Electronic module 101 can be picked up by pick-and-place equipment and placed on inner side 121 of base substrate 120. Interconnects 140 can be located on and coupled to substrate inward terminals 124a through a reflow, thermal compression, laser assisted, or other bonding process. Electronic components 110 of electronic module 101 can be electrically coupled to conductive structure 124 via substrate inward terminals 124a and interconnects 140.

Electronic components 110a and 110b can be coupled to substrate inward terminals 124a of base substrate 120. Electronic components 110a and 110b can be electrically coupled to electronic module 101 through base substrate 120. For example, electronic components 110a and 110b can be electrically coupled to electronic components 110 through conductive structure 124 of base substrate 120, interconnects 140, and conductive structure 134 of module substrate 130. Electronic components 110a and 110b can be positioned in an edge region of electronic module 101. For example, electronic components 110a can be positioned so as to be spaced apart from the sidewall of electronic module 101. In some examples, the thickness of electronic components 110a and 110b can each range from approximately 100 μm to approximately 200 μm.

In some examples, electronic components 110a or 110b can comprise or be referred to as a passive device, integrated passive device (IPD), power device, or intelligent power device. In some examples, electronic components 110a or 110b can comprise a capacitor. In some examples, electronic components 110a and 110b can comprise or be referred to as a die or a chip. Electronic components 110a and 110b can be arranged adjacent to electronic module 101 to improve power supply delivered to electronic components 110. Decreasing the distance between electronic components 110 and electronic components 110a and 110b can improve power efficiency of electronic device 100.

FIG. 2H shows a cross-section of example electronic device 100 at a later stage of manufacture. In the example shown in FIG. 2H, underfill 150a can be provided between module substrate 130 and base substrate 120. In accordance with various examples, underfill 150b can cover a lower side of electronic module 101. Underfill 150b can contact outer side 132 of module substrate 130, inner side 121 of base substrate 120, and interconnects 140. Underfill 150b can contact the sidewall of module substrate 130 and the sidewall of encapsulant 160a. In some examples, underfill 150b can also be provided between electronic component 110a and base substrate 120 and/or between electronic component 110b and base substrate 120.

Underfill 150b can comprise or be referred to as an insulating material. In some examples underfill 150b can be free of inorganic fillers. In accordance with various examples, the elements, features, materials, or manufacturing methods of underfill 150b can be similar to or the same as those described above for underfill 150a. Underfill 150b can reduce occurrences of electronic module 101 (and in some examples, electronic component 110b) separating from base substrate 120.

FIG. 2I shows a cross section of electronic device 100 at a later stage of manufacture. In the example shown in FIG. 2I, encapsulant 160b can be provided to cover electronic module 101, electronic components 110a and 110b, and base substrate 120. In some examples, encapsulant 160b can cover inner side 121 of base substrate 120, electronic components 110a and 110b, and electronic module 101. Encapsulant 160b can be in contact with inner side 121 of base substrate 120, electronic components 110a and 110b, and electronic module 101. For example, encapsulant 160b can contact encapsulant 160a and metal layer 174 of electronic module 101. In some examples, encapsulant 160b can contact underfill 150b, inner side 121 of base substrate 120, and the lateral sides of electronic module 101. In some examples, encapsulant 160b can be between base substrate 120 and electronic module 101 (e.g., between inner side 121 of base substrate 120 and outer side 132 of module substrate 130) and can contact interconnects 140. For example, encapsulant 160b can be a MUF and can replace underfill 150b. In accordance with various examples, the elements, features, materials, or manufacturing methods of encapsulant 160b can be similar to or that same as those of encapsulant 160a.

In some examples, the thickness of encapsulant 160b can be greater than the thickness of electronic module 101. The thickness of encapsulant 160b can range from approximately 100 μm to approximately 2000 μm. Encapsulant 160b can protect electronic module 101 and electronic components 110a and 110b from external elements.

FIG. 2J shows a cross section of electronic device 100 at a later stage of manufacture. the example shown in FIG. 2J, a portion of encapsulant 160b can be removed from upper side 160b1 of encapsulant 160b. FIG. 2J1 and 2J2 illustrate example channels 160b3 of region A in FIG. 2J in greater detail.

Although the example in FIG. 2J is depicted with metal layer 174 already coupled to the outer side 112 of electronic components 110 and encapsulant 160a, various embodiments can include module 101 lacking metal layer 174 prior to deposition of encapsulant 160b. In such embodiments, metal layer 174 can be provided subsequent to the upper sides of encapsulant 160a and electronic components 110 being exposed from encapsulant 160b. For example, encapsulant 160b can be removed to expose the upper sides of encapsulant 160a and electronic components 110, leaving encapsulant 160a substantially coplanar with encapsulant 160b. As used herein, the phrase “substantially coplanar” can mean within manufacturing tolerances of coplanarity. In examples that lack metal layer 174 at this stage, the metal layer 174 can be provided over encapsulant 160a, encapsulant 160a, and electronic components 110. In some examples, an edge region where adhesive 172 is later placed (see FIG. 2K) can be masked to allow adhesive 172 to be coupled directly to encapsulant 160b.

In various examples, a portion of encapsulant 160b can be removed inwardly from upper side 160b1 in a central region of encapsulant 160b to expose electronic module 101. The central region of encapsulant 160b can vertically overlap the footprint of electronic module 101. Removal of encapsulant 160b from the central region of encapsulant 160b can expose metal layer 174 (or expose electronic components 110 and encapsulant 160a in examples where metal layer 174 has not yet been provided). Removal of encapsulant 160b from the central region of encapsulant 160b can also form step portion 160b2 around the perimeter of electronic module 101.

In some examples, the height of the lower side of step portion 160b2 above substrate 120 can be less than the height upper side 160b1 above substrate 120. Step portion 160b2 can be coplanar with metal layer 174, or with electronic components 110 and encapsulant 160a in examples where metal layer 174 has not previously been provided. In some examples, step portion 160b2 can comprise or be referred to as a recessed portion. In some examples, the depth of step portion 160b2 can range from approximately 50 μm to approximately 1000 μm, and the lateral length L of step portion 160b2, as measured from the lateral side of module 101 to the vertically extending wall of step portion 160b2, can range from approximately 50 μm to approximately 1000, in some examples the lateral length L of step portion 160b2, can range from approximately 1 mm to approximately 5 mm.

In some examples, channel 160b3 can be provided in encapsulant 160b on the outer side of step portion 160b2. For example, channel 160b3 can be located between step portion 160b2 and the outer lateral side of encapsulant 160b. Channel 160b3 can be spaced apart from step portion 160b2. Upper side 160b1 can be located between step portion 160b2 and channel 160b3. Channel 160b3 can have a ring geometry or square geometry as viewed from above. Channel 160b3 can be provided by removing encapsulant 160b from upper side 160b1. Electronic components 110a and 110b can be disposed below channel 160b3. Encapsulant 160b can cover the upper sides of electronic components 110a and 110b with a reduced thickness due to channel 160b3 being disposed over electronic components 110a and 110b. Since encapsulant 160b exhibits relatively low thermal conductivity, the heat generated from electronic components 110a and 110b can be more easily expelled through the reduced thickness of encapsulant 160b positioned on the upper sides of electronic components 110a and 110b. In some examples, a thin region of encapsulant 160b can be positioned between the bottom of channel 160b3 and electronic components 110a and 110b. In some examples, the depth of channel 160b3 can be greater than the depth of step portion 160b2.

In some examples, channel 160b3 can comprise or be referred to as a groove. In some examples, the depth of channel 160b3 can range from approximately 50 μm to approximately 1000 μm, and the width of channel 160b3 can range from approximately 50 μm to approximately 1000 μm. In some examples, step portion 160b2 and channel 160b3 can be provided by removing a portion of encapsulant 160b. In some examples, portions of encapsulant 160b can be selectively removed from upper side 160b1 using a laser.

Examples in which metal layer 174 was not provided in an earlier step, metal layer 174 can be provided over encapsulant 160b, encapsulant 160a, and electronic components 110. For example, along step portions 160b2, upper side 160b1, and channel 160b3. Metal layer 174 can improved adhesion of metallic TIM.

The example of FIG. 2J1 shows angular or smooth walls of channel 160b3. The example of FIG. 2J2 shows a jagged, curved, or serrated side of channel 160b3. Though the examples shown in FIG. 2J1 and 2J2 are depicted using channel 160b3, the smooth surface treatment or jagged surface treatment can be applied to any side of encapsulant 160b configured to receive or contact a TIM. The serrated surface treatment of FIG. 2J2 can increase adhesion between encapsulant 160b and the TIM relative to a smooth surface treatment.

FIG. 2K shows a cross-section of example electronic device 100 at a later stage of manufacture. In the example of FIG. 2K, TIM 176 can be provided. TIM 176 can be provided over metal layer 174. Metal layer 174 can be interposed between TIM 176 and upper side of electronic module 101. In some examples, metal layer 174 can be interposed between TIM 176 and encapsulant 160b. Metal layer 174 can improve adhesion of TIM 176 and increase the bonding strength between TIM 176 and components of electronic device 100.

TIM 176 can be provided to substantially fill the inside of step portion 160b2 (e.g., fill the volume defined by step portion 160b2 and the upper side of electronic module 101) by dispensing or printing. As used herein, the phrase substantially fill can mean to fill a volume approximately 85% full, approximately 90% full, approximately 95% full, or approximately 100% full. In some examples, TIM 176 can be provided in a volume greater than the volume defined by step portion 160b2, which can cause TIM 176 to bulge above upper side 160b1 of encapsulant 160b. Using a greater volume of TIM 176 can decrease occurrences of voids in TIM 176. Reducing or eliminating TIM voids, particularly over electronic components 110, can improve heat dissipation from electronic module 101.

In some examples, TIM 176 can be a metallic TIM. TIM 176 can comprise a thermally conductive material or metallic material such as solder or solder paste. Examples of such TIMs 176 include metal alloy materials, such as gallium, gallium alloys (e.g., alloys with indium, tin, and zinc), silver alloys, tin-silver, indium, and indium alloys. TIM 176 can facilitate the transfer or conduction of heat generated from electronic components 110. Since TIM 176 includes a thermally conductive material, the heat generated from electronic components 110 can be easily transferred to lid 170 (FIG. 2L). In some examples, the thickness of TIM 176 can be greater than the thickness (depth) of step portion 160b2.

Lid adhesive 172 can be provided on upper side 160b1 of encapsulant 160b. Lid adhesive 172 can have a ring geometry or square geometry as viewed from above. Lid adhesive 172 can be provided on an edge region or perimeter of upper side 160b1 of encapsulant 160b. Step portion 160b2 and channel 160b3 can be positioned laterally inward from lid adhesive 172 as viewed from above. Lid adhesive 172 can be applied by, for example, dispensing lid adhesive 172 on upper side 160b1 of encapsulant 160b. Lid adhesive 172 can be an adhesive for attaching lid 170 (FIG. 2L) to encapsulant 160b. Lid adhesive 172 can include a thermal adhesive or a non-thermal adhesive. In some examples, the thickness of lid adhesive 172 can range from approximately 5 μm to 100 μm.

FIG. 2L shows a cross section of electronic device 100 at a later stage of manufacture. In the example shown in FIG. 2L, lid 170 can be provided over TIM 176 and encapsulant 160b.

Lid 170 can be coupled to TIM 176 and lid adhesive 172. Lid 170 can be a square or rectangular plate. In some examples, lid 170 can have trenches, protrusions, or fins on the upper surface thereof to improve heat dissipation efficiency. Lid 170 can be in contact with TIM 176 and lid adhesive 172. Lid 170 can be pressed towards TIM 176, urging TIM 176 towards an inner sidewall of lid adhesive 172, which can define a lateral boundary of TIM retention region 177. TIM retention region 177 can be defined by upper side 160b1 of encapsulant 160b, an upper side of metal layer 174, step portion 160b2, channel 160b3, lid adhesive 172, and a lower side of lid 170 once lid 170 is pressed into position. Structures of encapsulant 160a, metal layer 174, lid adhesive 172, and lid 170 can retain TIM 176 within TIM retention region 177.

In some examples, lid 170 can comprise or be referred to as a metal lid. For example, lid 170 can be formed of a metal or alloy (e.g., aluminum, nickel, copper, or alloys or combinations thereof). In some examples, lid 170 can be referred to as or comprise a heat sink, heat dissipation plate, cap, cover, encapsulation, or body. Lid 170 can protect electronic components 110a and 110b and electronic module 101 from external elements and allow heat generated from electronic components 110 to be quickly and easily dissipated. In some examples, the thickness of lid 170 can range from approximately 0.1 mm to approximately 5 mm.

After lid 170 is seated on TIM 176 and lid adhesive 172, TIM 176 and lid adhesive 172 can be cured through a curing process using heat, light, ultraviolet rays, laser, or any other suitable curing treatment. TIM 176 can be cured to reduce fluidity through a heat treatment in some examples. The pressing of lid 170 toward upper side 160b1 can cause TIM 176 to flow from step portion 160b2 to channel 160b3. For example, after filling the space between step portion 160b2 and lid 170, additional TIM 176 can flow into channel 160b3. TIM 176 can be disposed between step portion 160b2 and lid 170, between upper side 160b1 and lid 170, and between channel 160b3 and lid 170. Since TIM 176 completely or partially fills step portion 160b2, upper side 160b1, and channel 160b3 of encapsulant 160b, the bonding strength between TIM 176 and encapsulant 160b or metal layer 174 can be increased.

Lid 170 can have a central region coupled to metal layer 174 through TIM 176. Lid 170 can comprise edge regions bonded and fixed to encapsulant 160b (or metal layer 174) through lid adhesive 172 in some examples. In some examples, the thickness of TIM 176 filling step portion 160b2 can range from approximately 55 μm to approximately 1500 μm. In some examples, TIM 176 can flow in response to an increase in temperature within channel 160b3. TIM 176 can fill voids in TIM retention region 177.

FIG. 2M shows a cross-sectional view of electronic device 100 at a later stage of manufacture. In the example shown in FIG. 2M, external interconnects 180 can be provided on outer side 122 of base substrate 120.

External interconnects 180 can be coupled to outward terminals 124b of conductive structure 124. External interconnects 180 can be electrically coupled to electronic components 110, 110a, 110b, and 110d through conductive structure 124 of base substrate 120. In some examples, external interconnects 180 can comprise tin (Sn), silver (Ag), lead (Pb), copper (Cu), Sn—Pb, Sn37—Pb, Sn95—Pb, Sn—Pb—Ag, Sn—Cu, Sn—Ag, Sn—Au, Sn—Bi, or Sn—Ag—Cu. For example, external interconnects 180 can be formed by forming a conductive material including solder on outward terminals 124b through a ball drop method, followed by a reflow process. External interconnects 180 can comprise or be referred to as conductive balls such as solder balls, conductive pillars such as copper pillars, or conductive posts each having a solder cap formed on a metal (e.g., copper) pillar. In some examples, the sizes of external interconnects 180 can range from approximately 100μm to approximately 1000 μm. In some examples, external interconnects 180 can comprise or be referred to as external input/output terminals of electronic device 100. In some examples, electronic device 100 can be a land grid array (LGA) where outward terminals 124b serve as external input/output terminals and electronic device 100 can be devoid of external interconnects 180).

In some examples, one or more electronic components 110c can be provided on outer side 122 of base substrate 120. Electronic components 110c can be coupled to substrate outward terminals 124b of conductive structure 124. In accordance with various examples, the elements, features, materials, or manufacturing methods of electronic component(s) 110c can be similar to those of electronic components 110, 110a, or 110b. In some examples, electronic component 110c can comprise or be referred to as a die, a chip, a package, or a passive component. Electronic component 110b can be electrically coupled to electronic module 101, electronic components 110a and 110b, and/or external interconnects 180 through conductive structure 124 of base substrate 120.

In some examples, after providing external interconnects 180, a singulation process can be performed by sawing through saw streets to separate individual electronic devices 100. In some examples, base substrate 120 can be singulated (e.g., provided as discrete substrate units) prior to attaching electronic module 101.

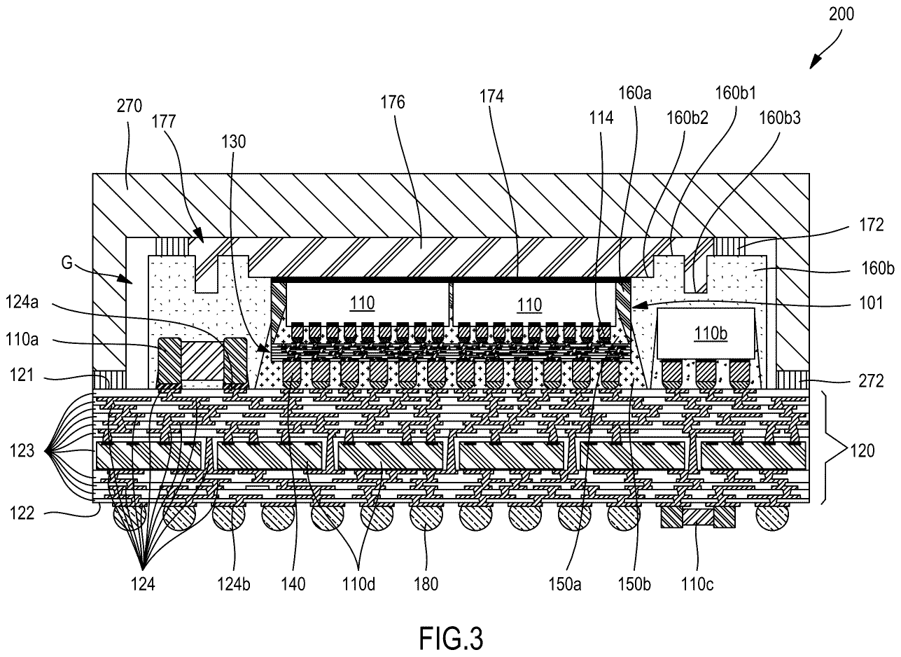

FIG. 3 shows a cross section of example electronic device 200. Electronic device 200 can comprise features and techniques similar to or the same as those of electronic device 100 or of any other electronic device described herein. In the example of FIG. 3, lid 270 can comprise a top plate and, in some examples, sidewalls extending downward from the top plate.

In accordance with various examples, the top plate and the sidewalls of lid 270 can be integral to one another (e.g., lid 270 can be a one-piece lid). In other examples, the top plate can be discrete from and bonded to the sidewalls (e.g., lid 270 can be a two-piece lid). In some examples, the top plate of lid 270 can have a trench, protrusions, or fins provided on the top side to improve heat dissipation efficiency. Electronic components 110a and 110b and electronic module 101 can be positioned in lid 270. For example, electronic components 110a and 110b and electronic module 101 can be in a cavity defined by the interior sides of the top plate and sidewalls of lid 270. Lid 270 can surround electronic components 110a and 110b and electronic module 101.

In some examples, the interior side of the top plate of lid 270 can contact TIM 176 and can be coupled to encapsulant 160b via lid adhesive 172. The sidewalls of lid 270 can be coupled to base substrate 120 via lid adhesive 272. In some examples, after lid 270 is seated on TIM 176 and lid adhesives 172 and 272, TIM 176 and/or lid adhesives 172 and 272 can be cured through a curing process by using heat, light, ultraviolet rays, laser, or any other suitable curing technique.

In some examples, TIM 176 of electronic device 200 can be contained within TIM retention region 177, as previously described. In some examples, a gap G can be defined between an inner sidewall of lid 270 and an outer sidewall of encapsulant 160b. TIM retention region 177 (e.g., lid adhesive 172) can prevent or reduce or occurrences of TIM 176 flowing into gap G.

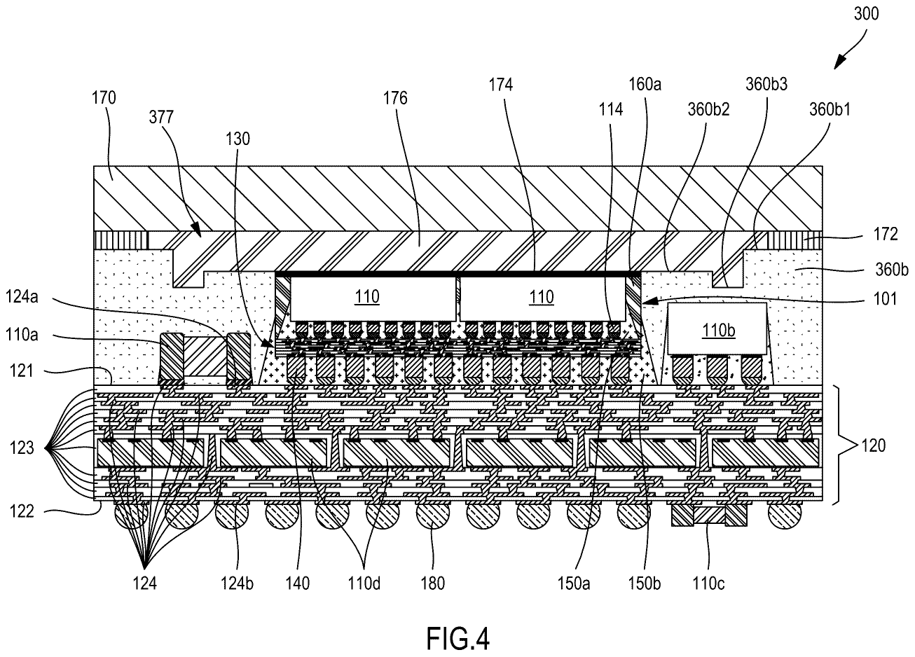

FIG. 4 shows a cross section of example electronic device 300. Electronic device 300 can comprise features and techniques similar to or the same as those of electronic device 100 or of any other electronic device described herein. In the example of FIG. 3, encapsulant 360b can comprise a different contour along the upper side than electronic device 100 of FIG. 1.

In the example of FIG. 4, electronic device 300 comprises encapsulant 360b over and coupled to inner side 121 of substrate 120. In some examples, encapsulant 360b can include side 360b2 substantially coplanar with metal layer 174. In examples where metal layer 174 is provided after encapsulant 360b, side 360b2 can be substantially coplanar with encapsulant 160a. Encapsulant 360b can also include side 360b1 having a height above base substrate 120 greater than a height of side 360b2 above base substrate 120. A channel 360b3 can be formed in encapsulant 360b. Channel 360b3 can be between side 360b1 and side 360b2. In some examples, channel 360b3 can have a recessed lower side and sidewalls having staggered (i.e., different) heights. For example, the sidewall of channel 360b3 adjacent side 360b2 can be shorter than the sidewall of channel 360b3 adjacent side 360b3. Lide adhesive 172 can be coupled to side 360b3 of encapsulant 360b and the inner side of lid 170.

In the example of electronic device 300, lid 170 comprises a substantially flat or planar plate. Lid 170 can be coupled to encapsulant 360b by lid adhesive 172. In some examples, the top side of lid 170 can have a trench, protrusions, or fins provided to improve heat dissipation. Electronic components 110a and 110b and electronic module 101 can be positioned under lid 170. The interior side of lid 170 can contact TIM 176. In some examples, lid 170 can be pressed towards encapsulant 360b, which can urge TIM 176 towards the inner sidewall of lid adhesive 172. The inner sidewall of adhesive 172 can define a lateral boundary of TIM retention region 377. TIM retention region 377 can be defined by an upper side of encapsulant 360b (e.g., by side 360b2, channel 360b3 and side 360b1), an upper side of metal layer 174, an inner side of lid adhesive 172, and a lower side of lid 170. Structures of encapsulant 360b, metal layer 174, lid adhesive 172, and lid 170 can retain TIM 176 within TIM retention region 377. After lid 170 is seated on TIM 176 and lid adhesive 172, TIM 176 and/or lid adhesive 172 can be cured through a curing process, as previously described.

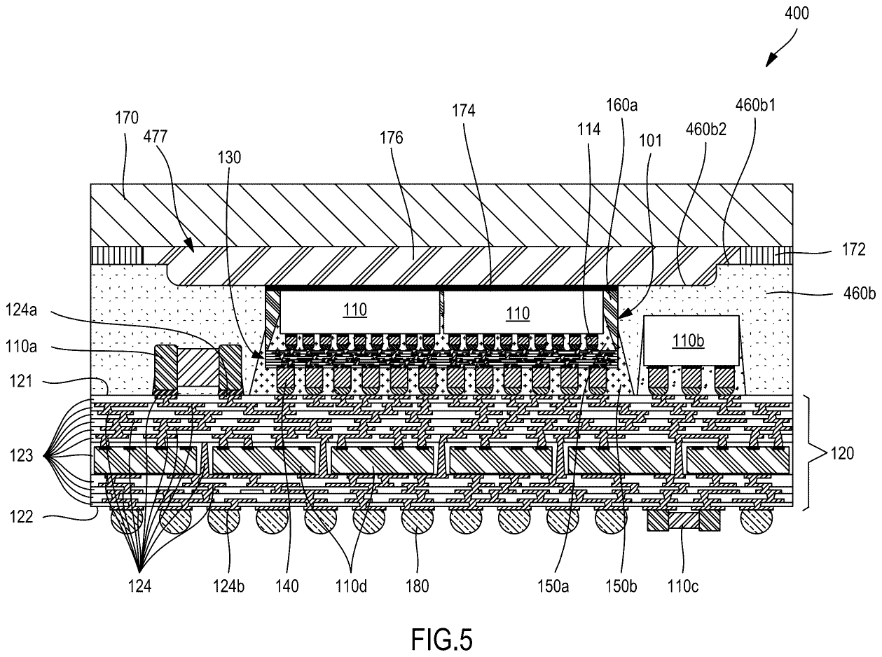

FIG. 5 shows a cross section of example electronic device 400. Electronic device 400 can comprise features and techniques similar to or the same as those of electronic device 100 or of any other electronic device described herein. In the example of FIG. 5, encapsulant 460b can comprise a different contour along the upper side than electronic device 100 of FIG. 1.

Electronic device 400 comprises encapsulant 460b over and coupled to inner side 121 of base substrate 120. In some examples, encapsulant 460b can include side 460b2, which is substantially coplanar with metal layer 174. In examples where metal layer 174 is provided after encapsulant 460b, side 460b2 can be substantially coplanar with encapsulant 160a of electronic module 101. Encapsulant 460b can also include side 460b1 having a height above base substrate 120 that is greater than a height of side 460b2 above base substrate 120. A trench of encapsulant 460b can be defined by inward-facing sidewalls connecting side 460b2 with side 460b1. The inward-facing sidewalls can comprise a rounded joint with side 460b2 in some examples. The inward-facing sidewalls can comprise a sharp joint (e.g., approximately 90 degrees) at a joint with side 460b1 in some examples.

Lid 170 can be in contact with TIM 176 and lid adhesive 172. Lid 170 can be pressed towards encapsulant 460b, urging TIM 176 towards the inner sidewall of lid adhesive 172. The inner sidewall of lid adhesive 172 can defining a lateral boundary of TIM retention region 477. TIM retention region 477 can be defined by an upper side of encapsulant 460b (e.g., by side 460b2, side 460b1 and the inward-facing sidewalls connecting side 460b2 with side 460b1), an upper side of metal layer 174, the inner sidewall of lid adhesive 172, and a lower side of lid 170. Structures of encapsulant 460b, metal layer 174, lid adhesive 172, and lid 170 can retain TIM 176 within TIM retention region 477.

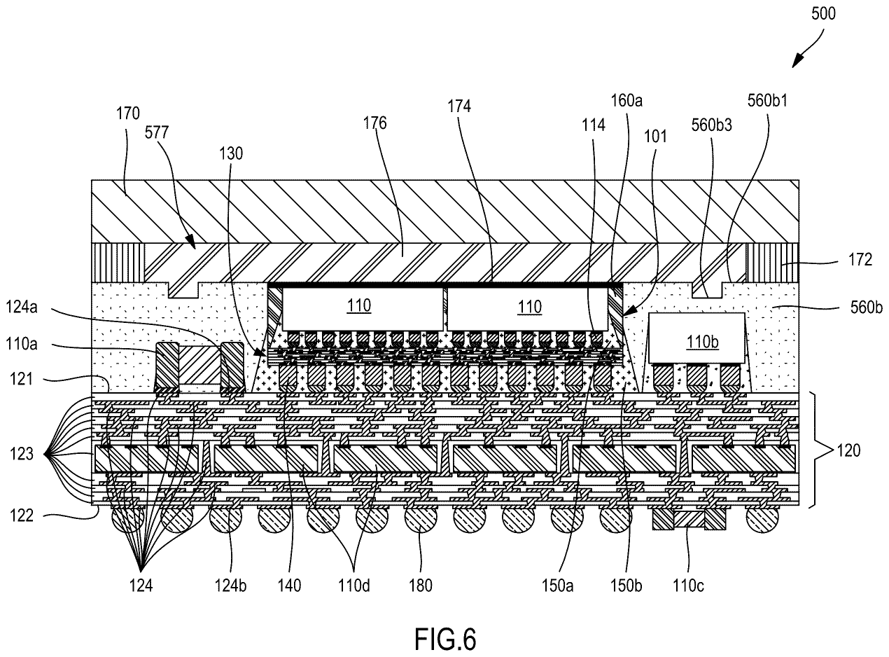

FIG. 6 shows a cross section of example electronic device 500. Electronic device 500 can comprise features and techniques similar to or the same as those of electronic device 100 or of any other electronic device described herein. In the example of FIG. 5, encapsulant 560b can comprise a different contour along the upper side than electronic device 100 of FIG. 1.

In some examples, encapsulant 560b can include upper side 560b1 substantially coplanar with metal layer 174. In examples where metal layer 174 is provided after encapsulant 560b, side 560b1 can be substantially coplanar with encapsulant 160a of electronic module 101. Encapsulant 560b can also comprise channel 560b3. Channel 560b3 can be formed into side 560b1, such that a height of the floor of channel 560b3, as measured from inner side 121 of base substrate 120, is less than a height of side 560b1, as measured from inner side 121 of base substrate 120. Channel 560b3 can include lateral sidewalls having a substantially same height.

Lid 170 can be in contact with TIM 176 and lid adhesive 172. Lid 170 can be pressed towards encapsulant 560b, which can urge TIM 176 towards the inner sidewall of adhesive 172. The inner sidewall of lid adhesive 172 can define a lateral boundary of TIM retention region 577. TIM retention region 577 can be defined by an upper side of encapsulant 560b (e.g., by side 560b1 and channel 560b3), an upper side of metal layer 174, the inner sidewall of lid adhesive 172, and a lower side of lid 170. Structures of encapsulant 560b, metal layer 174, lid adhesive 172, and lid 170 can retain TIM 176 within TIM retention region 577.

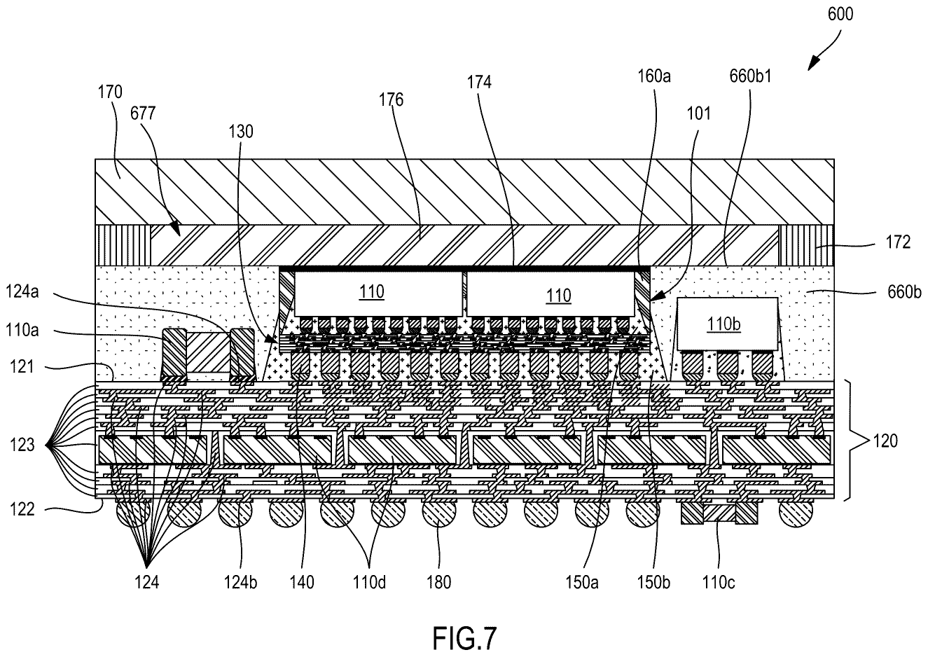

FIG. 7 shows a cross section of example electronic device 600. Electronic device 600 can comprise features and techniques similar to or the same as those of electronic device 100 or of any other electronic device described herein. In the example of FIG. 7, encapsulant 660b can comprise a different contour along the upper side than electronic device 100 of FIG. 1.

In some examples, encapsulant 660b can include an upper side 660b1 that is substantially coplanar with metal layer 174. In examples where metal layer 174 is provided after encapsulant 660b, side 660b1 can be substantially coplanar with encapsulant 160a of electronic module 101. In some examples, upper side 660b1 of encapsulant 660b can be substantially flat. Adhesive 172 can be coupled to upper side 660b1 of encapsulant 660b.

Lid 170 can be in contact with TIM 176 and lid adhesive 172. Lid 170 can be pressed towards encapsulant 660b, which can urge TIM 176 towards the inner sidewall of lid adhesive 172. The inner sidewall of lid adhesive 172 can define a lateral boundary of TIM retention region 677. TIM retention region 677 can be defined by an upper side of encapsulant 660b (e.g., upper side 660b1), an upper side of metal layer 174, the inner sidewall of lid adhesive 172, and a lower side of lid 170. Structures of encapsulant 660b, metal layer 174, lid adhesive 172, and lid 170 can retain TIM 176 within TIM retention region 677.

Various example electronic devices and related methods can improve reliability by inhibiting TIM from flowing onto electronic components. Electronic components 110a and 110b can be encapsulated to protect them from TIM flow. The encapsulant over electronic components 110a and 110b can be shaped to improve heat dissipation from electronic components 110a and 110b. The encapsulant can also be shaped to retain TIM within a TIM retention region and to adhere to TIM better than a flat or smooth encapsulant. Some examples include a BSM coupled to the encapsulant and to an electronic module, which can improve adhesion of the TIM over the encapsulant and over the electronic module. Some examples include surface treatments such as serrations or curvatures to improve adhesion between TIM and the encapsulant or electronic module.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a base substrate comprising:
a conductive structure; and
a dielectric structure interleaved with the conductive structure;
an electronic module coupled to the base substrate, the electronic module comprising:
a module substrate;
one or more electronic components coupled to the module substrate;
a first encapsulant disposed around lateral sides of the electronic components,
wherein an upper side of the first encapsulant is substantially coplanar with an upper side of the electronic components; and
a metal layer disposed over the upper side of the first encapsulant and the upper side of the electronic components;
a second encapsulant disposed around the electronic module, wherein the second encapsulant defines at least a portion of a TIM retention region;
a thermal interface material (TIM) disposed over the second encapsulant, over the metal layer, and in the TIM retention region; and
a lid disposed over the second encapsulant and the metal layer, wherein the lid is coupled to the TIM.

2. The electronic device of claim 1, wherein the second encapsulant comprises a channel formed in a first side of the second encapsulant and at least partially defining the TIM retention region.

3. The electronic device of claim 2, wherein a first height of a floor of the channel above the base substrate is less than a second height of the first side of the second encapsulant above the base substrate.

4. The electronic device of claim 2, wherein the second encapsulant comprises a step portion at least partially defining the TIM retention region.

5. The electronic device of claim 1, further comprising an adhesive coupled to a perimeter of the base substrate and to a perimeter of the lid, wherein a gap is defined between an inner sidewall of the lid and an outer sidewall of the second encapsulant.

6. The electronic device of claim 1, further comprising an adhesive coupled to the lid and the second encapsulant, wherein an inner sidewall of the adhesive at least partially defines the TIM retention region.

7. The electronic device of claim 1, wherein the second encapsulant further comprises a serrated side at least partially defining the TIM retention region.

8. The electronic device of claim 1, further comprising a trench at least partially defining the TIM retention region, wherein a sidewall of the trench comprises an inner wall of the second encapsulant, wherein in the inner wall of the second encapsulant connects a first side of the second encapsulant and a second side of the second encapsulant, and wherein a floor of the trenchcomprises a portion of the first side of the second encapsulant and an upper side of the metal layer.

9. The electronic device of claim 1, wherein the second encapsulant comprises a channel including an inner sidewall and an outer sidewall, wherein the inner sidewall is closer to the electronic module than the outer sidewall, wherein a first height of the inner sidewall is less than a second height of the outer sidewall.

10. An electronic device, comprising:
a base substrate;
an electronic module coupled to the base substrate and comprising electronic components, a first encapsulant disposed around lateral sides of the electronic components, and a metal layer disposed over the first encapsulant and the electronic components;
a second encapsulant disposed around the electronic module and the metal layer, wherein the second encapsulant and the metal layer at least partially define a TIM retention region;
a thermal interface material (TIM) disposed over the second encapsulant and over the metal layer, wherein the TIM is retained within a footprint of the base substrate; and
a lid disposed over the second encapsulant and the metal layer, wherein the lid is coupled to the TIM.

11. The electronic device of claim 10, wherein the second encapsulant comprises a channel configured to receive a flow of the TIM.

12. The electronic device of claim 11, wherein the second encapsulant comprises a step portion configured to receive a flow of the TIM.

13. The electronic device of claim 10, further comprising an adhesive coupled to a perimeter of the base substrate and to a perimeter of the lid, wherein a gap is defined between an inner sidewall of the lid and an outer sidewall of the second encapsulant.

14. The electronic device of claim 10, further comprising an adhesive coupled to the lid and the second encapsulant, wherein an inner sidewall of the adhesive is configured to retain a flow of the TIM within the footprint of the base substrate.

15. The electronic device of claim 10, wherein the second encapsulant further comprises a serrated side.

16. A method of manufacturing an electronic device, comprising:
providing a base substrate comprising a conductive structure and a dielectric structure interleaved with the conductive structure;
providing an electronic module over the base substrate, the electronic module comprising an electronic component and a first encapsulant around lateral sides of the electronic component;
providing a metal layer over the first encapsulant and the electronic component;
providing a second encapsulant over the base substrate and around lateral sides of the electronic module;
providing an adhesive over the second encapsulant, wherein the adhesive defines a lateral boundary of a thermal interface material (TIM) retention region over the second encapsulant;
providing a TIM over the second encapsulant and the metal layer; and
providing a lid over the TIM, wherein the lid is coupled to the second encapsulant by the adhesive.

17. The method of claim 16, wherein providing the second encapsulant further comprises removing a portion of the second encapsulant to form a channel in the second encapsulant.

18. The method of claim 16, wherein providing the second encapsulant further comprises removing a portion of the second encapsulant to form a step in the second encapsulant.

19. The method of claim 16, wherein the lid comprises a top plate and sidewalls extending from the top plate.

20. The method of claim 16, further comprising providing a serrated side in the second encapsulant.
